(19) United States
(12) Patent Application Publication
(10) Pub. No.: US 2010/0099255 A1
(43) Pub. Date: Apr. 22, 2010

(54) METHOD OF FORMING A CONTACT THROUGH AN INSULATING LAYER

(76) Inventors: Willard E. Conley, Schenectady, NY (US); Massud Abubaker Aminpur, Hopewell Junction, NY (US); Cesar M. Garza, Poughkeepsie, NY (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 12/254,338

(22) Filed: Oct. 20, 2008

(51) Int. Cl. H01L 21/44

(52) U.S. Cl. 438/675; 257/E21.476

(57) ABSTRACT

A method includes forming an insulating layer over a substrate, forming a masking layer over the insulating layer, forming a developable bottom anti-reflective coating (BARC) over the masking layer, forming a first photo resist layer over the developable BARC, exposing and developing portions of both the first photo resist layer and the developable BARC to form a first set of openings in the developable BARC, forming a second photo resist layer over the first set of openings and the developable BARC, exposing and developing portions of both the second photo resist layer and the developable BARC to form a second set of openings in the developable BARC, and extending each opening in the first and second set of openings through the masking layer and the insulating layer.

### BACKGROUND

1. Field

This disclosure relates generally to semiconductor devices, and more specifically, to making contact through an insulating layer in a semiconductor device.

2. Related Art

Forming a contact through an insulating layer typically includes first forming an opening in the insulating layer and filling the opening with opening with conductive material. This is also known as via formation. The lithography in defining the location of the opening has continued to improve but there are limitations limit how close the openings can be for a given exposure. Alignment has also continued to improve. Although it may be difficult to expose openings closer together than 125 nanometers, alignment capability has reached 5 nanometers or even lower. This has given rise to a double exposure approach that overcomes the single exposure lithographic limitation. A first set of openings are made based on a first exposure followed by forming a second set of openings using a second exposure with a different mask. This sequential formation of openings, however, has given rise to difficult issues due to the affects of forming the second opening after the first opening. Although it can be done, there are desirable affects that may be difficult to achieve using two openings.

Thus, there is a need for an approach of reducing the spacing between openings below the lithographic limit while retaining desirable characteristics in forming the openings.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 is a cross section of a semiconductor device at a stage in processing according to an embodiment;

FIG. 2 is a cross section of a semiconductor device at a stage in processing subsequent to that shown in FIG. 1;

FIG. 3 is a cross section of a semiconductor device at a stage in processing subsequent to that shown in FIG. 2;

FIG. 4 is a cross section of a semiconductor device at a stage in processing subsequent to that shown in FIG. 3;

FIG. 5 is a cross section of a semiconductor device at a stage in processing subsequent to that shown in FIG. 4;

FIG. 6 is a cross section of a semiconductor device at a stage in processing subsequent to that shown in FIG. 5;

FIG. 7 is a cross section of a semiconductor device at a stage in processing subsequent to that shown in FIG. 6;

FIG. 8 is a cross section of a semiconductor device at a stage in processing subsequent to that shown in FIG. 7;

FIG. 9 is a cross section of a semiconductor device at a stage in processing subsequent to that shown in FIG. 8;

FIG. 10 is a cross section of a semiconductor device at a stage in processing subsequent to that shown in FIG. 9;

FIG. 11 is a cross section of a semiconductor device at a stage in processing subsequent to that shown in FIG. 10;

FIG. 12 is a cross section of a semiconductor device at a stage in processing subsequent to that shown in FIG. 11; and

FIG. 13 is a cross section of a semiconductor device at a stage in processing subsequent to that shown in FIG. 12.

### DETAILED DESCRIPTION

A stack of layers, including an insulating layer through which vias will be formed, is formed over contacts in preparation for forming the vias. The stack includes the insulating layer over the contacts, a sacrificial layer over the insulating layer, a masking layer over the sacrificial layer, a developable anti-reflective coating (ARC) is formed over the sacrificial layer, and a photoresist layer is formed over the developable ARC. The photoresist and developable ARC are exposed with a first pattern for contact openings. This pattern of openings is made through the photoresist and the developable ARC. The patterned photoresist is removed and replaced by a second photoresist layer. The second photoresist layer and the developable ARC are exposed with a second contact opening pattern. Openings in the second photoresist layer and the developable ARC are formed according to the second pattern. Both the first and second patterns are extended into the masking layer at the same time. The pattern of openings in the masking layer is extended into the sacrificial layer. The pattern of openings in the sacrificial layer is extended into the insulating layer. The resulting openings in the insulating layer extend to the contacts and are filled with conductive material to form vias to the contacts.

The semiconductor substrate described herein can be any semiconductor material or combinations of materials, such as gallium arsenide, silicon germanium, silicon-on-insulator (SOI), silicon, monocrystalline silicon, the like, and combinations of the above. A via is considered an opening in an insulating layer filled with conductive material whereby electrical contact is made through the insulating layer.

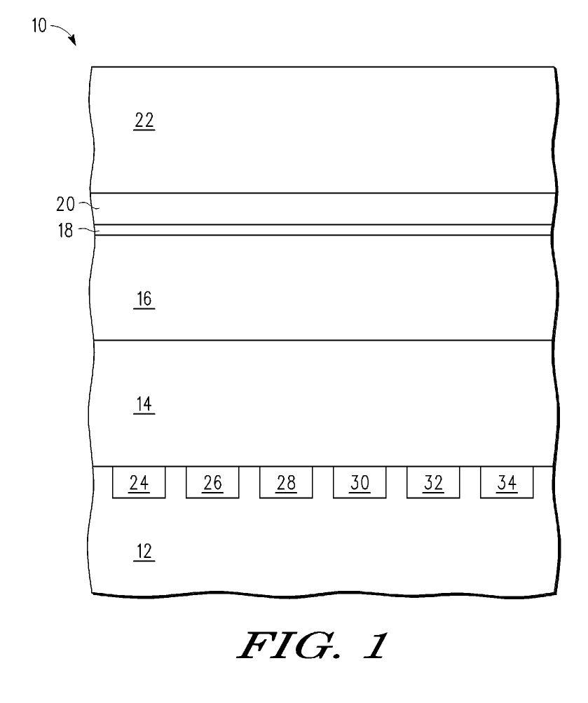

Shown in FIG. 1 is a semiconductor device 10 comprising a supporting layer 12, an insulating layer 14 over supporting layer 14, a sacrificial layer 16 over supporting layer 16, a masking layer 18 over sacrificial layer 16, a developable ARC layer 20 over masking layer 20, and a photoresist layer 22 over developable ARC layer 20. At a top surface of supporting layer 12 are spaced apart contacts 24, 26, 28, 30, 32, and 34 (24-34). These contacts may be for lines such as bit lines are simply contacts to any circuitry. Contacts are often thought of as round or square but they can also be shaped differently such as like a line. Supporting layer 12 may be a semiconductor substrate to which contacts 24-34 are electrically connected to active regions or may be an insulating layer over which conductive lines run. Sacrificial layer 14 may be amorphous carbon. Masking layer 18 may be oxide such as low temperature oxide (LTO). Developable ARC may be an organic ARC that is developable in the same manner as photoresist. Such organic ARCs are readily available commercially and are spun on in the same manner as photoresist.

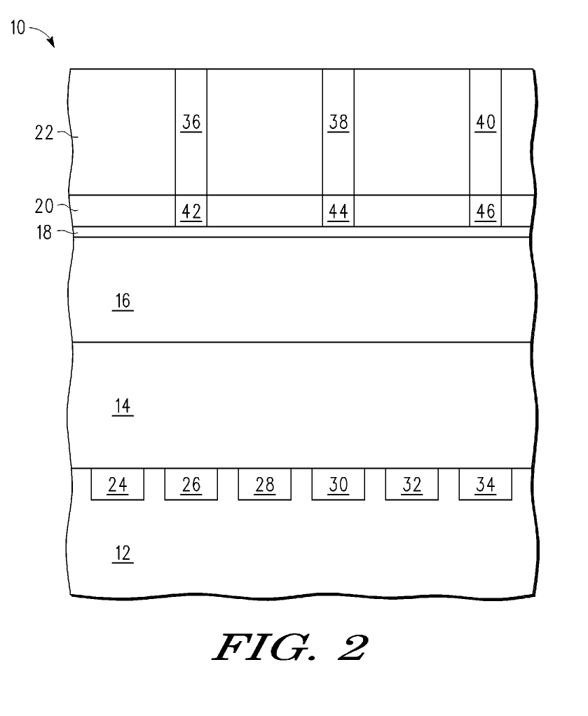

Shown in FIG. 2 is semiconductor device 10 after exposing photoresist layer 22 and developable ARC 20 according to a first pattern resulting in exposed portions 36, 38, and 40 in photoresist layer 22 and exposed portions 42, 44, and 46 in developable ARC 20. Portions 42, 44, and 46 are aligned with and under portions 36, 38, and 40.

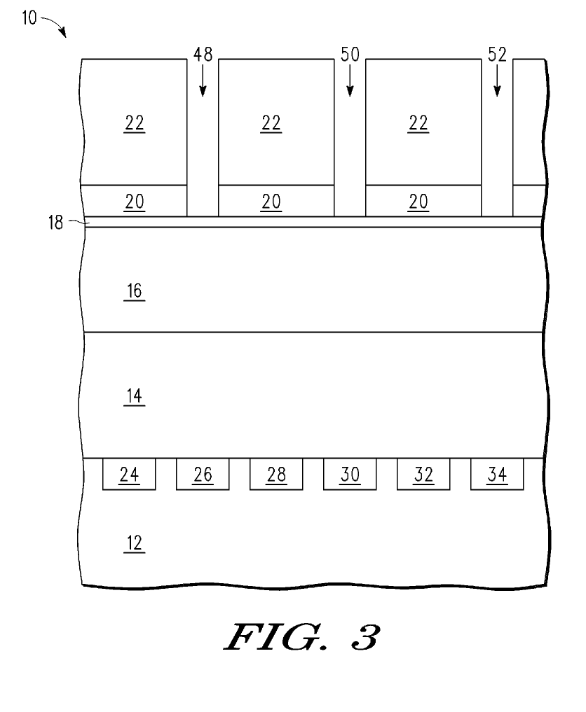

Shown in FIG. 3 is semiconductor device 10 after removing exposed portions 42, 44, 46, 36, 38, and 40. This removal is easily achieved using a developer. This leaves openings 48, 50, and 52 in photoresist layer 22 and developable ARC layer 20 aligned to contacts 26, 30, and 34, respectively. Openings 48, 50, and 52, with further processing, will be extended to expose contacts 26, 30, and 34, respectively. Masking layer 18 acts to prevent the developer from reaching sacrificial layer 16. Amorphous carbon is removable, at least to some extent, using developer. Thus, masking layer 18 prevents sacrificial layer 16, at least in the case of sacrificial layer 16 being amorphous carbon, from being adversely impacted during the application of developer to photoresist layer 22 and developable ARC layer 20.

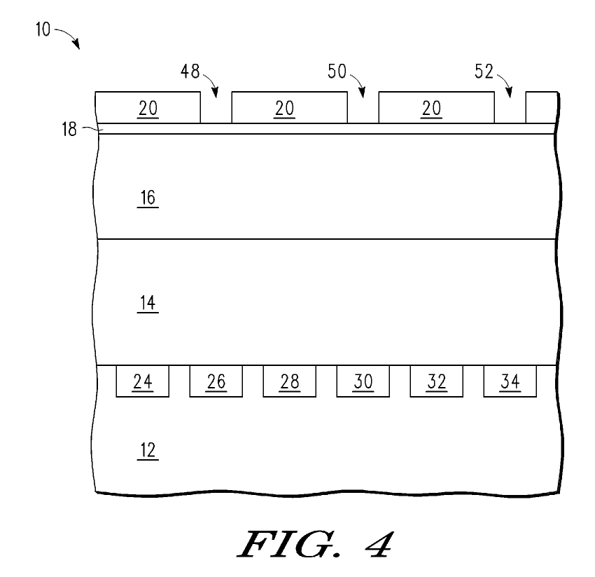

Shown in FIG. 4 is semiconductor device 10 after removing photoresist layer 22. These leaves openings 48, 50, and 52 in developable ARC layer 20. The removal of photoresist layer 22 is achieved using a conventional photoresist removal technique. A beneficial characteristic of developable ARC layer 20 is that it is not impacted by the application of the conventional photoresist removal technique.

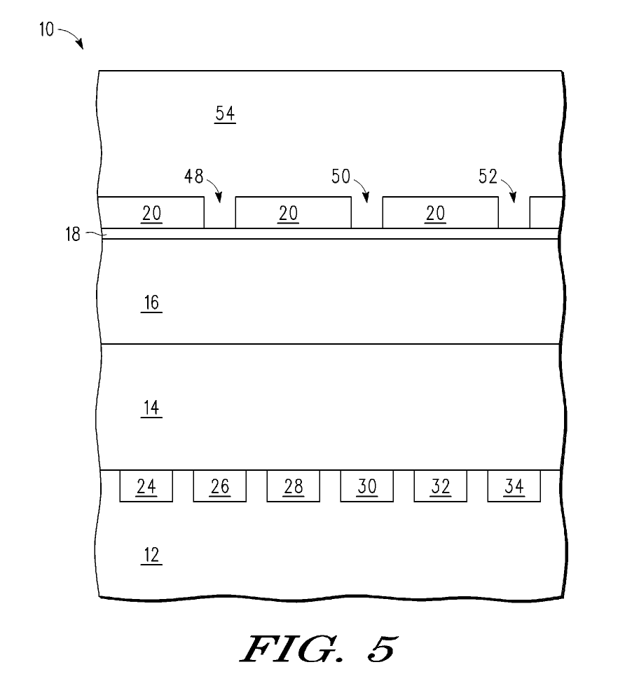

Shown in FIG. 5 is semiconductor device 10 after applying a photoresist layer 54 that covers developable ARC 20 and fills openings 48, 50, and 52.

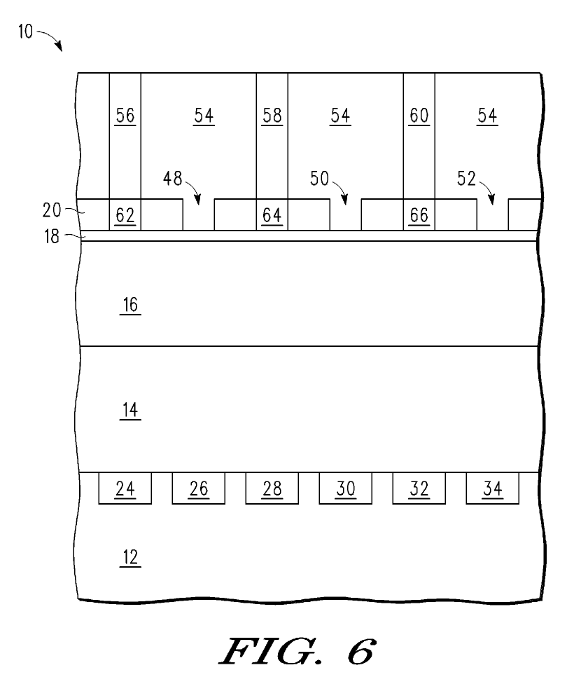

Shown in FIG. 6 is semiconductor device 10 after exposing photoresist layer 54 and developable ARC 20 according to a second pattern resulting in exposed portions 56, 58, and 60 in photoresist layer 54 and exposed portions 62, 64, and 66 in developable ARC 20. Portions 62, 64, and 66 are aligned with and under portions 56, 58, and 60.

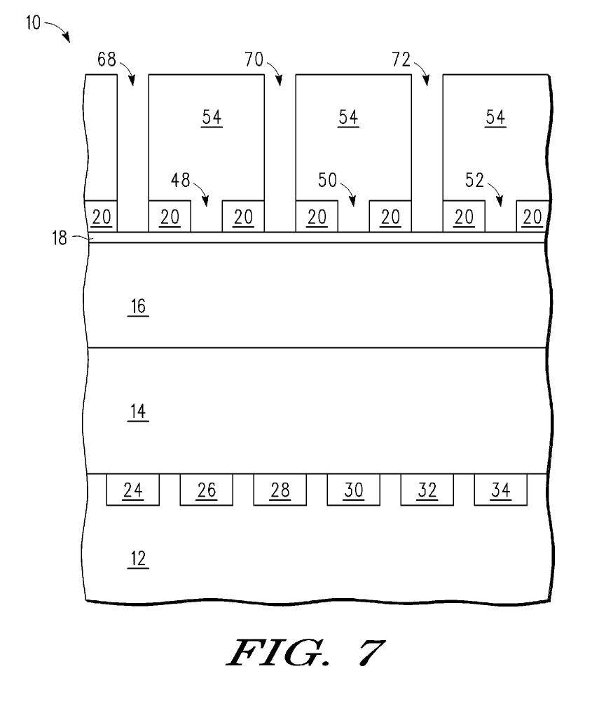

Shown in FIG. 7 is semiconductor device 10 after removing exposed portions 56, 58, 60, 62, 64, and 66. This removal is easily achieved using a developer. This leaves openings 68, 70, and 72 in photoresist layer 54 and developable ARC layer 20 aligned to contacts 24, 28, and 32, respectively. Openings 68, 70, and 72, with further processing, will be extended to expose contacts 24, 28, and 32, respectively. Masking layer 18 again acts to prevent the developer from reaching sacrificial layer 16. Thus, masking layer 18 again prevents sacrificial layer 16, at least in the case of sacrificial layer 16 being amorphous carbon, from being adversely impacted during the application of developer to photoresist layer 54 and developable ARC layer 20.

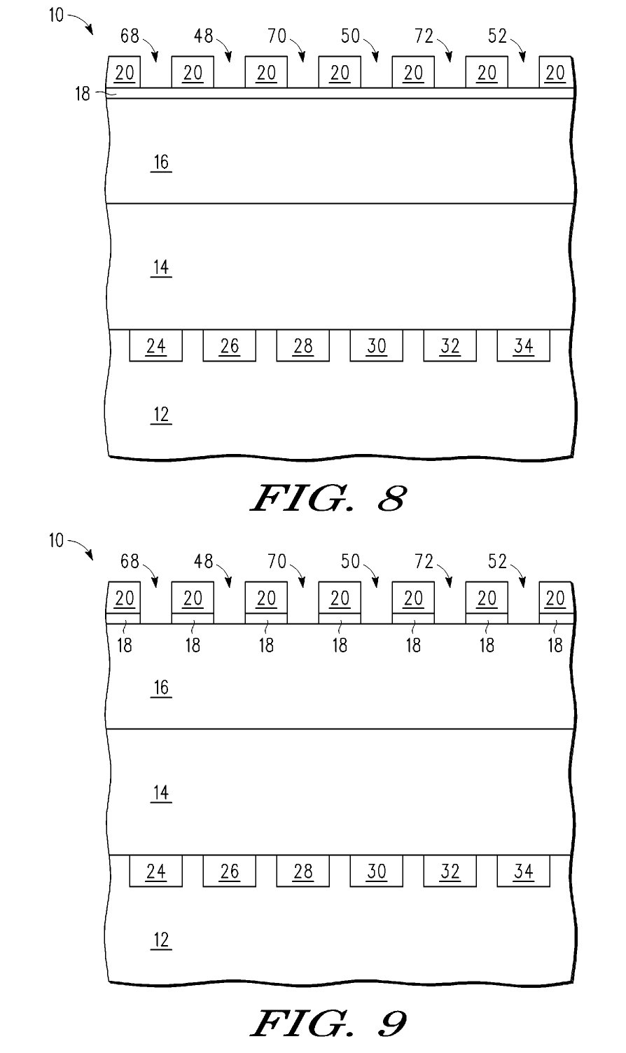

Shown in FIG. 8 is semiconductor device 10 after removing photoresist layer 84. These leaves openings 68, 70, and 72 in developable ARC layer 20. The removal of photoresist layer 84 is achieved using a conventional photoresist removal technique. Again, a beneficial characteristic of developable ARC layer 20 is that it is not impacted by the application of the conventional photoresist removal technique. The result is that there is an opening in developable ARC layer 20 that is aligned to the contacts at the surface of supporting layer 12. The spacing between openings is better than is lithographically feasible using just one exposure of photoresist. For example, the space between opening 68 and opening 48 is less than is feasible for a single exposure of photoresist. Further sacrificial layer 16 has been protected by masking layer 18 during the processing performed to achieve openings 48, 50, 52, 68, 70, and 72. This etch may reduce the thickness of developable ARC 20.

Shown in FIG. 9 is semiconductor device 10 after etching through masking layer 18 so that openings 48, 50, 52, 68, 70, and 72 extend through masking layer 18. This exposes portions of sacrificial layer 16 aligned to contacts 24-34.

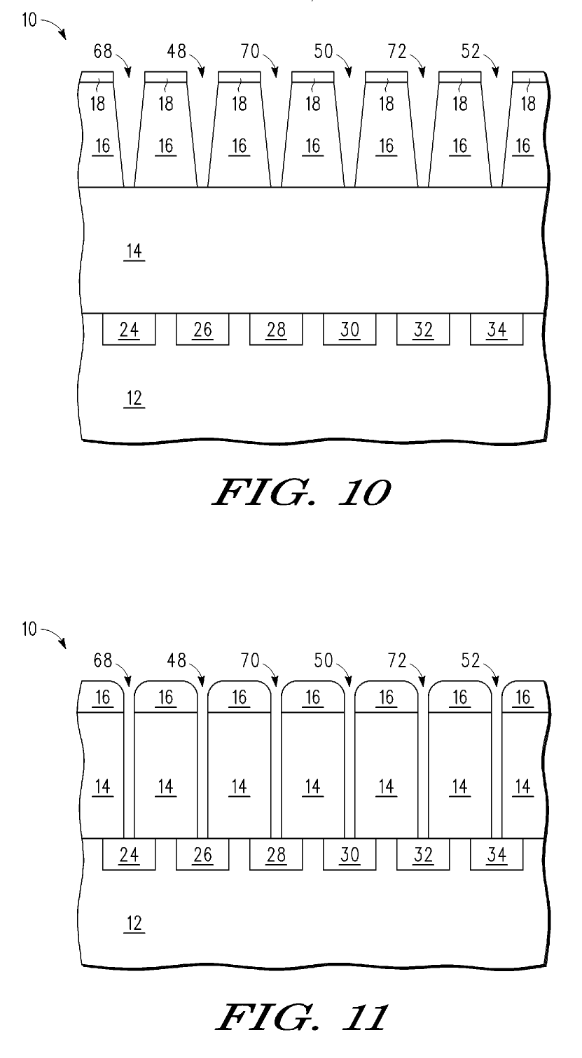

Shown in FIG. 10 is semiconductor device 10 after etching through sacrificial layer 16 using masking layer 18 as a mask to extend openings 48, 50, 52, 68, 70, and 72 through sacrificial layer 16 and to insulating layer 14. Openings 48, 50, 52, 68, 70, and 72 through sacrificial layer 16 are sloped so as to reduce the diameter of openings 48, 50, 52, 68, 70, and 72 at a top surface of insulating layer 14. Amorphous carbon is particularly beneficial for this purpose because the slope can be easily controlled. Other materials can also be used for this purpose and etches can be adjusted to achieve slopes. Amorphous carbon is comparatively easier to control in achieving a repeatable and desirable slope. The use of masking layer 18 to prevent developer from reaching sacrificial layer 16 helps uniformity of openings 48, 50, 52, 68, 70, and 72 through sacrificial layer 16.

Shown in FIG. 11 is semiconductor device 10 after an etch extending openings 48, 50, 52, 68, 70, and 72 through insulating layer 14 to expose contacts 24-34. Because typical etchants that etch insulating layers have little selectivity to amorphous carbon, most of sacrificial layer 16 is removed during the extension of openings 48, 50, 52, 68, 70, and 72 through insulating layer 14. Due to the slope of openings 48, 50, 52, 68, 70, and 72 through sacrificial layer 16, when these openings are extended through insulating layer 14, openings 48, 50, 52, 68, 70, and 72 are substantially narrower than when originally made through photoresist layers 22 and 54.

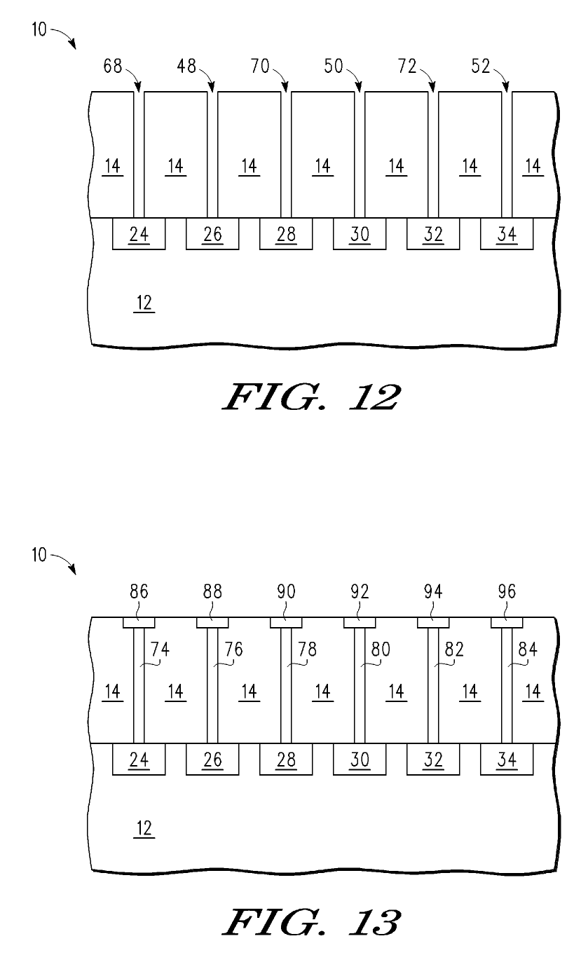

Shown in FIG. 12 is semiconductor device 10 after removing what remained of sacrificial layer 16 after being used in the formation of 48, 50, 52, 68, 70, and 72 through insulating layer 14.

Shown in FIG. 13 is semiconductor device 10 after filling openings 68, 48, 70, 50, 72, and 52 in insulating layer 14 with conductive fills 74, 76, 78, 80, 82, and 84, respectively. Additionally, contacts 86, 88, 90, 92, 94, and 96 have been formed in the surface of insulating layer 14 and are in contact with conductive fills 74, 76, 78, 80, 82, and 84, respectively. Conductive fills 74, 76, 78, 80, 82, and 84 through openings 68, 48, 70, 50, 72, and 52, respectively, constitute vias. Contact is thus formed between contacts 24, 26, 28, 30, 32, and 34 and contacts 86, 88, 90, 92, 94, and 96, respectively, through insulating layer 14 using conductive fills 74, 76, 78, 80, 82, and 84, respectively.

The result shown in FIG. 13 is a desired structure for making contact through an insulating layer and has the contacts closer together than would normally be feasible than through using a single exposure to identify the openings. This is achieved with uniformity and repeatability using a masking layer and a sacrificial layer between the insulating layer and the combination of developable ARC and photoresist. Some of the benefit may be achievable with just one of the sacrificial layer and the masking layer with the proper choice of materials. A solution for double patterning is achieved with a reduced number of process steps. An all clean track solution provides a double patterning solution with a single vacuum etch step. This potentially applies to non-double patterning solutions.

By now it should be appreciated that there has been provided a method that includes forming an insulating layer over a substrate. The method further includes forming a masking layer over the insulating layer. The method further includes forming a developable bottom anti-reflective coating (BARC) over the masking layer. The method further includes forming a first photo resist layer over the developable BARC. The method further includes exposing and developing portions of both the first photo resist layer and the developable BARC to form a first set of openings in the developable BARC. The method further includes forming a second photo resist layer over the first set of openings and the developable BARC. The method further includes exposing and developing portions of both the second photo resist layer and the developable BARC to form a second set of openings in the developable BARC. The method further includes extending each opening in the first and second set of openings through the masking layer and the insulating layer. The method may be further characterized by the step of extending each opening being further characterized as extending each opening in the first and second set of openings through the masking layer and the insulating layer to expose contact pads in the substrate. The method may further comprise filling each opening in the first and second set of openings with a conductive material. The method may further comprise forming a sacrificial layer over the insulating layer, wherein the masking layer is formed over the sacrificial layer. The method may be further characterized by the step of extending each opening further comprising extending each opening in the first and second set of openings from the developable BARC through the masking layer, extending each opening in the first and second set of openings from the masking layer through the sacrificial layer, and extending each opening in the first and second set of openings from the sacrificial layer through the insulating layer. The method may be further characterized by the step of extending each opening in the first and second set of openings from the masking layer through the sacrificial layer being further characterized in that each opening in the first and second set of openings is tapered as it extends through the sacrificial layer. The method may further include removing the sacrificial layer after the step of extending each opening in the first and second set of openings from the sacrificial layer through the insulating layer. The method may be further characterized by the step of forming the sacrificial layer being further characterized in that the sacrificial layer comprises amorphous carbon. The method may be further characterized by the step of forming the masking layer being further characterized in that the masking layer comprises a low temperature oxide. The method may be further characterized by the steps of forming the insulating layer, forming the masking layer, forming the developable BARC, forming the first photo resist layer, exposing and developing portions of both the first photo resist layer and the developable BARC, forming the second photo resist layer, and exposing and developing portions of both the second photo resist layer and the developable BARC be performed in a same clean track.

Also described is a method that includes forming an insulating layer over a substrate. The method further includes forming a sacrificial layer over the insulating layer. The method further includes forming a masking layer over the sacrificial layer. The method further includes forming a developable bottom anti-reflective coating (BARC) over the masking layer. The method further includes forming a first photo resist layer over the developable BARC. The method further includes exposing and developing portions of both the first photo resist layer and the developable BARC to form a first set of openings in the developable BARC. The method further includes forming a second photo resist layer over the first set of openings and the developable BARC. The method further includes exposing and developing portions of both the second photo resist layer and the developable BARC to form a second set of openings in the developable BARC. The method further includes forming a third set of openings in the masking layer, wherein the third set of openings is defined by the first and second set of openings in the developable BARC. The method further includes forming a fourth set of openings in the sacrificial layer, wherein the fourth set of openings is defined by the third set of openings in the masking layer. The method further includes forming a fifth set of openings in the insulating layer, wherein the fifth set of openings is defined by the fourth set of openings in the sacrificial layer. The method may further comprise, after the step of forming the fifth set of openings in the insulating layer, removing the sacrificial layer and filling the fifth set of openings with a conductive material. The method may be further characterized by the step of forming the fifth set of openings is further characterized in that each opening of the fifth set of openings exposes a contact pad in the substrate. The method may be further characterized by the step of forming the fourth set of openings being further characterized in that each opening of the fourth set of openings is tapered as it extends through the sacrificial layer. The method may be further characterized by the step of forming the fourth set of openings being further characterized in that each opening of the fourth set of openings is tapered as it extends through the sacrificial layer. The method may be further characterized by the step of forming the sacrificial layer being further characterized in that the sacrificial layer comprises amorphous carbon. The method may be further characterized by the step of forming the masking layer being further characterized in that the masking layer comprises an oxide.

Described also is a method including forming an insulating layer over a substrate having contact pads. The method further includes forming an amorphous carbon layer over the insulating layer. The method further includes forming a masking layer over the amorphous carbon layer. The method further includes forming a developable bottom anti-reflective coating (BARC) over the masking layer. The method further includes forming a first photo resist layer over the developable BARC. The method further includes exposing and developing portions of both the first photo resist layer and the developable BARC to form a first set of openings in the developable BARC. The method further includes forming a second photo resist layer over the first set of openings and the developable BARC. The method further includes exposing and developing portions of both the second photo resist layer and the developable BARC to form a second set of openings in the developable BARC. The method further includes forming a third set of openings in the masking layer, wherein the third set of openings is defined by the first and second set of openings in the developable BARC. The method further includes forming a fourth set of openings in the amorphous carbon layer, wherein the fourth set of openings is defined by the third set of openings in the masking layer. The method further includes forming a fifth set of openings in the insulating layer, wherein the fifth set of openings is defined by the fourth set of openings in the amorphous carbon layer and wherein each opening in the fifth set of openings exposes an underlying contact pad in the substrate. The method further includes filling the fifth set of openings with a conductive material. The method may further include, after the step of forming the fifth set of openings in the insulating layer, removing the amorphous carbon layer. The method may be further characterized by the step of forming the fourth set of openings being further characterized in that each opening of the fourth set of openings is tapered as it extends through the amorphous carbon layer.

Although the invention is described herein with reference to specific embodiments, various modifications and changes can be made without departing from the scope of the present invention as set forth in the claims below. For example, a different material than oxide may be able to be used for insulating for masking layer 18. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

The term “coupled,” as used herein, is not intended to be limited to a direct coupling or a mechanical coupling.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

1. A method comprising:
forming a plurality of contact pads over a substrate;
forming an insulating layer over the plurality of contact pads;
forming a masking layer over the insulating layer;
forming a developable bottom anti-reflective coating (BARC) over the masking layer;
forming a first photo resist layer over the developable BARC;
exposing and developing portions of both the first photo resist layer and the developable BARC to form a first set of openings in the developable BARC wherein the first set of openings stop on the masking layer whereby the first set of openings do not extend through the masking layer and wherein the first set of openings are aligned to a first subset of contact pads of the plurality of contact pads;
forming a second photo resist layer over the first set of openings and the developable BARC and on the masking layer in the first set of openings;
exposing and developing portions of both the second photo resist layer and the developable BARC to form a second set of openings in the developable BARC wherein the second set of openings are aligned to a second subset of contact pads of the plurality of contact pads;
extending, after the step of exposing and developing portions of both the second photo resist layer and the developable BARC, each opening in the first and second set of openings through the masking layer and the insulating layer to form extended openings through the insulating layer that expose the plurality of contact pads; and
filling the extended openings in the insulating layer with conductive material.

2-3. (canceled)

4. The method of claim 1, further comprising:
forming a sacrificial layer over the insulating layer, wherein the masking layer is formed over the sacrificial layer and the extended opening extend through the sacrificial layer.

5. (canceled)

6. The method of claim 4, wherein the step of extending each opening in the first and second set of openings from the masking layer through the sacrificial layer is further characterized in that each opening in the first and second set of openings is tapered as it extends through the sacrificial layer.

7. The method of claim 4, further comprising:
removing the sacrificial layer after the step of extending each opening in the first and second set of openings from the sacrificial layer through the insulating layer.

8. The method of claim 4, wherein the step of forming the sacrificial layer is further characterized in that the sacrificial layer comprises amorphous carbon.

9. The method of claim 1, wherein the step of forming the masking layer is further characterized in that the masking layer comprises a low temperature oxide.

10. The method of claim 1, wherein the steps of forming the insulating layer, forming the masking layer, forming the developable BARC, forming the first photo resist layer, exposing and developing portions of both the first photo resist layer and the developable BARC, forming the second photo resist layer, and exposing and developing portions of both the second photo resist layer and the developable BARC are performed in a same clean track.

11. A method comprising:
forming a plurality of contact pads over a substrate;
forming an insulating layer over the plurality of contact pads;
forming a sacrificial layer over the insulating layer;
forming a masking layer over the sacrificial layer;
forming a developable bottom anti-reflective coating (BARC) over the masking layer;
forming a first photo resist layer over the developable BARC;
exposing and developing portions of both the first photo resist layer and the developable BARC to form a first set of openings in the developable BARC extending to the masking layer to expose the masking layer in the first set of openings but not extending through the masking layer, wherein the first set of openings are aligned to a first subset of contact pads of the plurality of contact pads;
forming a second photo resist layer over and in the first set of openings and the developable BARC;
exposing and developing portions of both the second photo resist layer and the developable BARC to form a second set of openings in the developable BARC, wherein the second set of openings are aligned to a second subset of contact pads of the plurality of contact pads;
forming a third set of openings in the masking layer, wherein the third set of openings is defined by the first and second set of openings in the developable BARC, wherein the third set of openings are formed simultaneously;
forming a fourth set of openings in the sacrificial layer, wherein the fourth set of openings is defined by the third set of openings in the masking layer, wherein the fourth set of openings are formed simultaneously;
forming a fifth set of openings in the insulating layer, wherein the fifth set of openings is defined by the fourth set of openings in the sacrificial layer, wherein the fifth set of openings are formed simultaneously and expose the plurality of contacts; and
filling the fifth set of openings with conductive material.

12. The method of claim 11, further comprising:
after the step of forming the fifth set of openings in the insulating layer, removing the sacrificial layer.

13. (canceled)

14. The method of claim 13, wherein the step of forming the fourth set of openings is further characterized in that each opening of the fourth set of openings is tapered as it extends through the sacrificial layer.

15. The method of claim 11, wherein the step of forming the fourth set of openings is further characterized in that each opening of the fourth set of openings is tapered as it extends through the sacrificial layer.

16. The method of claim 11, wherein the step of forming the sacrificial layer is further characterized in that the sacrificial layer comprises amorphous carbon.

17. The method of claim 11, wherein the step of forming the masking layer is further characterized in that the masking layer comprises an oxide.

18. A method comprising:
forming an insulating layer over a substrate having contact pads;
forming an amorphous carbon layer over the insulating layer;
forming a masking layer over the amorphous carbon layer;
forming a developable bottom anti-reflective coating (BARC) over the masking layer;
forming a first photo resist layer over the developable BARC;
exposing and developing portions of both the first photo resist layer and the developable BARC to form a first set of openings in the developable BARC extending to the masking layer to expose the masking layer in the first set of openings but not extending through the masking layer, wherein the first set of openings are aligned to a first subset of contact pads of the plurality of contact pads;
forming a second photo resist layer over the first set of openings and the developable BARC;
exposing and developing portions of both the second photo resist layer and the developable BARC to form a second set of openings in the developable BARC, wherein the second set of openings are aligned to a second subset of contact pads of the plurality of contact pads;
forming a third set of openings in the masking layer, wherein the third set of openings is defined by the first and second set of openings in the developable BARC, wherein the third set of openings are formed simultaneously;
forming a fourth set of openings in the amorphous carbon layer, wherein the fourth set of openings is defined by the third set of openings in the masking layer, wherein the fourth set of openings are formed simultaneously;
forming a fifth set of openings in the insulating layer, wherein the fifth set of openings is defined by the fourth set of openings in the amorphous carbon layer and wherein each opening in the fifth set of openings exposes an underlying contact pad in the substrate, wherein the fifth set of openings are formed simultaneously and expose the plurality of contacts; and
filling the fifth set of openings with a conductive material.

19. The method of claim 18, further comprising:
after the step of forming the fifth set of openings in the insulating layer, removing the amorphous carbon layer.

20. The method of claim 18, wherein the step of forming the fourth set of openings is further characterized in that each opening of the fourth set of openings is tapered as it extends through the amorphous carbon layer.
